(19) United States
(12) Patent Application Publication
(10) Pub. No.: US 2009/0004885 A1
(43) Pub. Date: Jan. 1, 2009

(54) Method for fabricating semiconductor device

(75) Inventor: Koji Komatsu, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/155,638

(22) Filed: Jun. 6, 2008

(30) Foreign Application Priority Data
Jun. 29, 2007 (JP) 2007-172928

(51) Int. Cl. H01L 21/469

(52) U.S. Cl. 438/782; 257/E21.271

(57) ABSTRACT

An object of the present invention is to provide a method for fabricating a semiconductor device capable of implementing planarization of an insulating film formed on a semiconductor substrate formed thereon with a circuit pattern and inhibiting unevenness of a film thickness of the insulating film, and a device thereof.

According to the present invention, when etching is progressed to an A-A line, a part of a BPSG film 14 is exposed from an SOG film 16. A point at which the part of the BPSG film 14 is exposed is an “exposure start point”. A change of a plasma emission intensity of oxygen atoms during etching is observed to detect the “exposure start point”. An EPD detection in which an “etching end point” is set using the “exposure start point” as a reference is performed. The etching is continued even after a start of exposure of the BPSG film 14. Before a B-B line at which an entire surface of the BPSG film 14 is exposed is reached, the etching is ended at a C-C line.

### CROSS REFERENCE TO RELATED APPLICATION

This application claims the priority of Application No. 2007-172928, filed Jun. 29, 2007 in Japan, the subject matter of which is incorporated herein by reference.

### TECHNICAL FIELD OF THE INVENTION

The present invention relates to a method for fabricating a semiconductor device and a device thereof, and more particularly, relates to a method for fabricating a semiconductor device in which on a semiconductor substrate formed thereon with a circuit pattern, a silicon oxide film and a spin on glass film (SOG film), as an insulating film, are formed in this order, and the insulating film is planarized by plasma etching, and a device thereof.

### BACKGROUND OF THE INVENTION

Along with higher integration of a semiconductor device, a multilayer interconnection in which a wiring is 3-dimensionally laid out via an interlayer insulating film is adopted. In the multilayer interconnection, to form a wiring pattern accurately, it is important to planarize the underlying insulating film. The wiring pattern is formed using a resist mask. When there is a step in the insulating film, at the time of forming the resist mask by photolithography, the influence of a reflected light by an underlying step leads to the generation of a pattern defect, such as “slimming” and “notch” in the resist pattern. As a result, the wiring pattern cannot be formed accurately.

Conventionally, a technique of planarizing the insulating film includes: (1) a “heat flow process” in which by applying a high temperature process, the step is alleviated; (2) an “etching-back process” in which an SOG film is formed as a sacrificial film on a silicon oxide film such as a BPSG film, etc., and an entire surface thereof is etched back for planarization; and (3) a “CMP process” for planarizing by chemical mechanical polishing. In particular, the “etching-back process” is generally used as the planarization technique(Patent Documents 1, 2, and 3).

FIGS. 9A to 9D are cross-sectional views illustrating each step of the conventional etching-back process. In the conventional etching-back process, as shown in FIG. 9A, on a semiconductor substrate 12 formed thereon with a circuit pattern 10 such as an aluminum wiring, etc., a BPSG film 14 is formed as an insulating film. On a surface of the BPSG film 14, a step created by the circuit pattern 10 is reflected. Subsequently, as shown in FIG. 9B, on the BPSG film 14, an SOG film 16 of which the surface is nearly planarized is formed, and in this state, planarization by plasma etching is started.

Even after the BPSG film 14 is exposed from the SOG film 16 along an A-A line, the etching is continued until a B-B line, and thereby, as shown in FIG. 9C, an entire surface of the BPSG film 14 is exposed, and a surface 14B is planarized. As shown in FIG. 9D, on the planarized surface 14B, a resist mask 18 can be formed accurately.
[Patent Document 1] JP-A-H5-55181
[Patent Document 2] JP-A-H6-29414
[Patent Document 3] JP-A-H9-283516

However, in the conventional heat flow process, although uniformity of a film thickness of the insulating film can be implemented, the heat flow process cannot provide a planarization effect to the extent that the resist mask having a fine pattern can be manufactured accurately. Further, in the etching-back process or the CMP process, although the planarization effect is greater as compared to the heat flow process, unevenness is generated in the film thickness of the insulating film.

FIG. 10 is a partial cross-sectional view illustrating the unevenness of the thickness of the insulating film. For example, as shown in FIG. 10, between a portion (stepped portion) in which the circuit pattern 10 is formed on the semiconductor substrate 12 and that (planarized portion) in which the circuit pattern 10 is not formed on the semiconductor substrate 12, the thickness of the insulating film differs. Therefore, an aspect ratio L₂₀ of a contact hole 20 formed in the stepped portion and an aspect ratio L₂₂ of a contact hole 22 formed in the planarized portion differ greatly in value. Herein, the aspect ratio (L) is a value expressed by L=film thickness d/hole diameter r. The film thickness (hole depth) d and the hole diameter r are defined as in FIG. 11.

That is, there is a problem in that when the film thickness of the insulating film has unevenness, it becomes necessary to form the contact holes having different aspect ratios between the stepped portion and the planarized portion, and thus, the processing of the insulating film becomes difficult. In particular, in the planarized portion having the thick insulating film, it is difficult to surely form a contact hole having a large (deep) aspect ratio.

On the other hand, in the etching-back process, there is also a problem in that after the silicon oxide film such as a BPSG film, etc., is exposed, oxygen generated from the silicon oxide film speeds up an etching rate of the SOG film, and thus, the planarization of the insulating film deteriorates locally.

### OBJECTS OF THE INVENTION

The present invention has been achieved to solve the above-described problems, and an object of the present invention is to provide a method for fabricating a semiconductor device capable of implementing planarization of an insulating film formed on a semiconductor substrate, on which a circuit pattern thereon. Another object of the present invention is to avoid unevenness of a film thickness of the insulating film, and a device thereof.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a method for fabricating a semiconductor device of the present invention comprises: stacking on a semiconductor substrate formed thereon with a circuit pattern, a silicon oxide film and a spin on glass film (SOG film), as an insulating film, in this order; starting planarization of the insulating film by plasma etching; observing a temporal change of a plasma emission intensity of oxygen atoms during the etching to detect an exposure start point of the silicon oxide film of which the plasma emission intensity becomes constant, and then, starts increasing again; and ending the plasma etching at the exposure start point or within a predetermined time from the exposure start point.

In the method for fabricating a semiconductor device, the plasma etching is preferably ended before an entire-surface exposed point of the silicon oxide film of which the plasma emission intensity becomes constant again. The silicon oxide film preferably is a silicon oxide film (a BPSG film) to which phosphorus and boron are added.

According to a second aspect of the present invention, a device for fabricating a semiconductor device comprises: an etching apparatus for applying plasma etching to a semiconductor substrate formed thereon with a circuit pattern, the semiconductor substrate having thereon a silicon oxide film and a spin on glass film (SOG film), as an insulating film, formed in this order on the circuit pattern; observing means for observing a temporal change of a plasma emission intensity of oxygen atoms during etching; detecting means for detecting, based on an observation result of the observing means, an exposure start point of the silicon oxide film of which the plasma emission intensity becomes constant, and then, starts increasing again; and stopping means for stopping the plasma etching at the exposure start point detected by the detecting means or within a predetermined time from the exposure start point.

According to the present invention, there is an effect that planarization of an insulating film formed on a semiconductor substrate formed thereon with a circuit pattern is implemented and unevenness of a film thickness of the insulating film can be inhibited.

### BRIEF DESCRIPTION OF THE DRAWINGS

FIG. 1 is a schematic view illustrating an etching apparatus according to the present invention.

FIGS. 2A to 2E are cross-sectional views showing etching-back process according to the present invention.

FIG. 3 is a diagram illustrating a state in which a contact hole is formed in an insulating film shown in FIG. 2E.

FIG. 4A is a graph showing a temporal change of a plasma emission intensity of oxygen atoms in the conventional etching-back process.

FIG. 4B is a graph showing a temporal change of a plasma emission intensity of oxygen atoms in an etching-back process of the present invention.

FIG. 5 is a flowchart showing a process routine of an etching control process.

FIGS. 6A to 6E are SEM pictures of a surface of an insulating film of example 1.

FIGS. 7A to 7E are SEM pictures of a surface of an insulating film of comparative example 1.

FIGS. 8A to 8E are SEM pictures of a surface of an insulating film of comparative example 2.

FIGS. 9A to 9D are cross-sectional views showing each step of the conventional etching-back process.

FIG. 10 is a partial cross-sectional view showing unevenness of a thickness of an insulating film shown in FIG. 9(C).

FIG. 11 is a diagram for defining a calculation element of an aspect ratio of a contact hole.

### DESCRIPTION OF REFERENCE NUMERALS

10: Circuit pattern
12: Semiconductor substrate
14: BPSG film
16: SOG film
18: Resist mask
20: Contact hole
22: Contact hole
24: Contact hole
26: Contact hole
30: Etching apparatus
32: Vacuum chamber
34: Gas inlet
36: Gas outlet
38: Processed object
40: Lower electrode
42: Upper electrode
44: Observation window
44: High frequency power supply
46: Filter
48: Light sensor
50: Analog/digital converter
52: Computer

### DETAILED DISCLOSURE OF THE INVENTION

In the following detailed description of the preferred embodiment, reference is made to the accompanying drawings which form a part hereof, and in which is shown by way of illustration specific preferred embodiment in which the inventions may be practiced. This preferred embodiment is described in sufficient detail to enable those skilled in the art to practice the invention, and it is to be understood that other preferred embodiments may be utilized and that logical, mechanical and electrical changes may be made without departing from the spirit and scope of the present invention. The following detailed description is, therefore, not to be taken in a limiting sense, and scope of the present invention is defined only by the appended claims.

Hereinafter, with reference to drawings, one example of an embodiment of the present invention is described in detail.

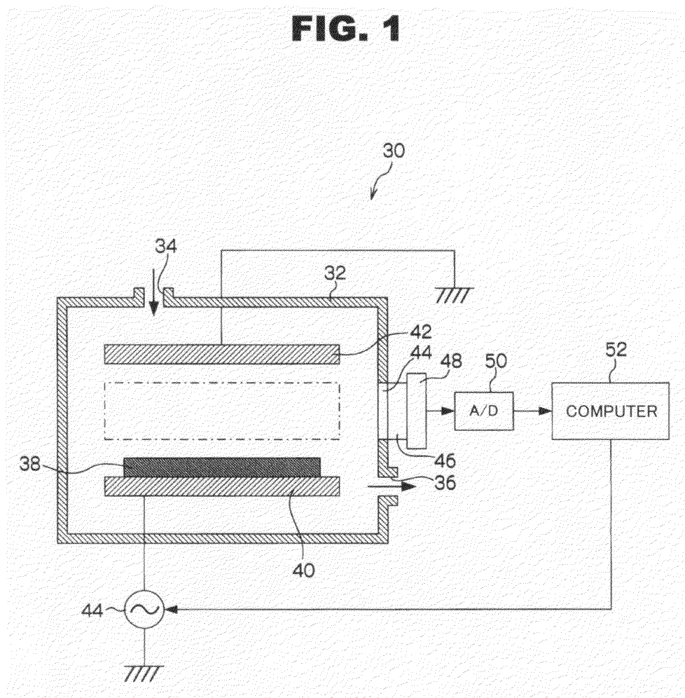

FIG. 1 is a schematic view illustrating a configuration of an etching apparatus according to the embodiment of the present invention. An etching apparatus 30 is provided with a vacuum chamber 32 for sealing reactive gas therein. The vacuum chamber 32 is formed with a gas inlet 34 for introducing the reactive gas and a gas outlet 36 for discharging the gas to outside.

Inside the vacuum chamber 32, a flat-plate-like lower electrode 40 for mounting a processed object 38 and a flat-plate-like upper electrode 42 arranged in parallel to face the lower electrode 40 are provided. The lower electrode 40 is connected to a high frequency power supply (RF) 44, and the upper electrode 42 is grounded. When the reactive gas is introduced and a high frequency voltage is applied to the lower electrode 40 by the high frequency power supply 44, a plasma is generated between (in about a region surrounded by a dashed line) the lower electrode 40 and the upper electrode 42.

A side wall of the vacuum chamber 32 is formed with an observation window 44 for observing a plasma emission during etching. Outside (on a light transmission side) of the observation window 44, a filter 46 for transmitting light at a specific wavelength is arranged. Herein, a temporal change of a light intensity of the plasma emission of oxygen atoms is observed. A wavelength of the plasma emission of the oxygen atoms is about 777 nm. Therefore, the filter 46 which transmits light of 777 nm in wavelength is arranged. Outside the filter 46, a light sensor 48 for detecting the light which transmits the filter 46 is arranged. The light sensor 48 detects the light intensity of the plasma emission and converts it into an electrical signal.

The light sensor 48 is connected via an analog/digital converter 50 to a computer 52. An analog signal output from the light sensor 48 is converted at the analog/digital converter 50 into a digital signal and is input to the computer 52. The computer 52 is connected to a controller (not shown) of the high frequency power supply 44, and turns on and off the high frequency power supply 44 by a control signal.

The computer 52 is provided with a CPU, a ROM, a RAM, and an input/output port for connecting to an external device. The CPU, the ROM, the RAM, and the input/output port are interconnected via a bus. A program stored in the ROM is read in the RAM, which is a working area, and the read program is executed. The CPU is operated based on the program read in the RAM. The ROM stores a program for executing an etching control process described later.

The configuration of these allows the computer 52 to successively obtain the electrical signal indicative of the light intensity of the plasma emission of the oxygen atoms from the light sensor 48, to observe the temporal change of the plasma emission intensity of the oxygen atoms during etching, and to execute the etching control process which ends etching of the processed object 38. The etching control process is described later.

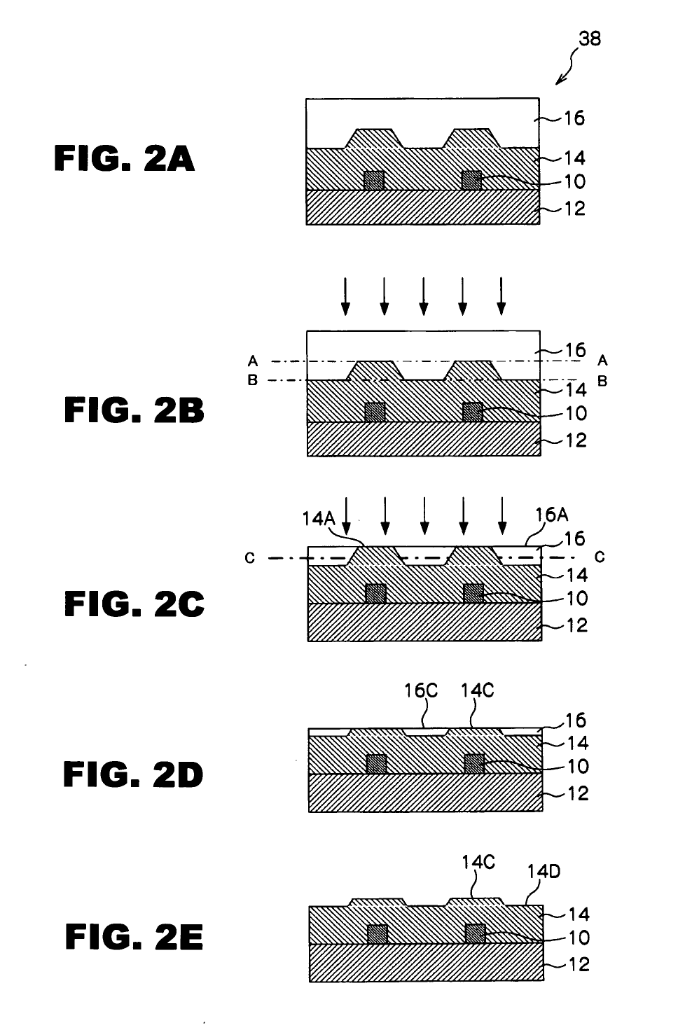

Subsequently, an etching-back process using the above-described etching apparatus 30 is described. FIGS. 2A to 2E are cross-sectional views showing each step of the etching-back process of the present invention.

As shown in FIG. 2A, on the semiconductor substrate 12 formed thereon with the circuit pattern 10 such as an aluminum wiring, the processed object 38 formed therein with the BPSG film 14 and the SOG film 16, as an insulating film, in this order is prepared. The BPSG film 14 is formed to have a nearly constant thickness, and on the surface of the BPSG film 14, a step created by the circuit pattern 10 is reflected. The SOG film 16 is formed to bury the step on the surface of the BPSG film 14 so that the surface is nearly planarized.

Subsequently, as shown in FIG. 2B, the planarization by the plasma etching is started. The processed object 38 is mounted on the lower electrode 40 inside the vacuum chamber 32 so that the insulating film faces upwardly. In an interior of the vacuum chamber 32, “reactive gas” in which trifluoromethane (CHF₃) and oxygen (O₂), for example, are mixed is introduced from the gas inlet 34, and the high frequency power supply 44 is turned on to generate a plasma between the lower electrode 40 and the upper electrode 42. Thereby, the insulating film on the semiconductor substrate 12 is etched from the surface.

As shown in FIG. 2C, when the etching is progressed to an A-A line, a part of the BPSG film 14 is exposed from the SOG film 16. This exposed surface is defined as 14A. A point at which the surface 14A of the BPSG film 14 is exposed is an “exposure start point”. In the conventional etching-back process, the etching is continued even after a start of the exposure of the BPSG film 14, and after a B-B line at which the entire surface of the BPSG film 14 is exposed is reached, the etching is ended. A point at which the entire surface of the BPSG film 14 is exposed is an “entire-surface exposed point”. In contrary thereto, in the present embodiment, although the etching is continued even after the start of the exposure of the BPSG film 14, the etching is ended at a C-C line before reaching the B-B line at which the entire surface of the BPSG film 14 is exposed.

When the etching reaches the C-C line, on the surface of the insulating film, a surface 14C of the stepped portion of the BPSG film 14 and a surface 16C of the SOG film 16 are exposed, as shown in FIG. 2D. Thereby, the step of the BPSG film 14 is alleviated, implementing the planarization. As shown in FIG. 2E, the remaining SOG film 16 can be removed by another method such as a wet etching, etc., by hydrofluoic acid (HF), for example. In this case, the surface 14C of the stepped portion of the BPSG film 14 and the surface 14D of the planarized portion of the BPSG film 14 are exposed.

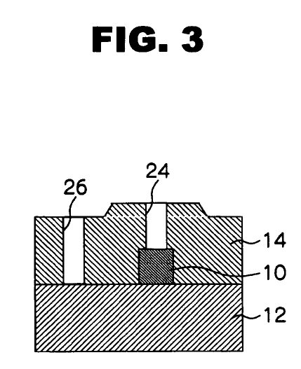

FIG. 3 is a diagram illustrating a state in which a contact hole is formed in the insulating film shown in FIG. 2E. When the etching is ended before the entire surface of the BPSG film 14 is exposed, as shown in FIG. 2E, unevenness of a thickness of the insulating film generated between a portion (stepped portion) in which the circuit pattern 10 is formed on the semiconductor substrate 12 and a portion (planarized portion) in which the circuit pattern 10 is not formed on the semiconductor substrate 12 is inhibited. As a result, as shown in FIG. 3, an aspect ratio L₂₄ of a contact hole 24 formed in the stepped portion and an aspect ratio L₂₆ of a contact hole 26 formed in the planarized portion become nearly equal in value.

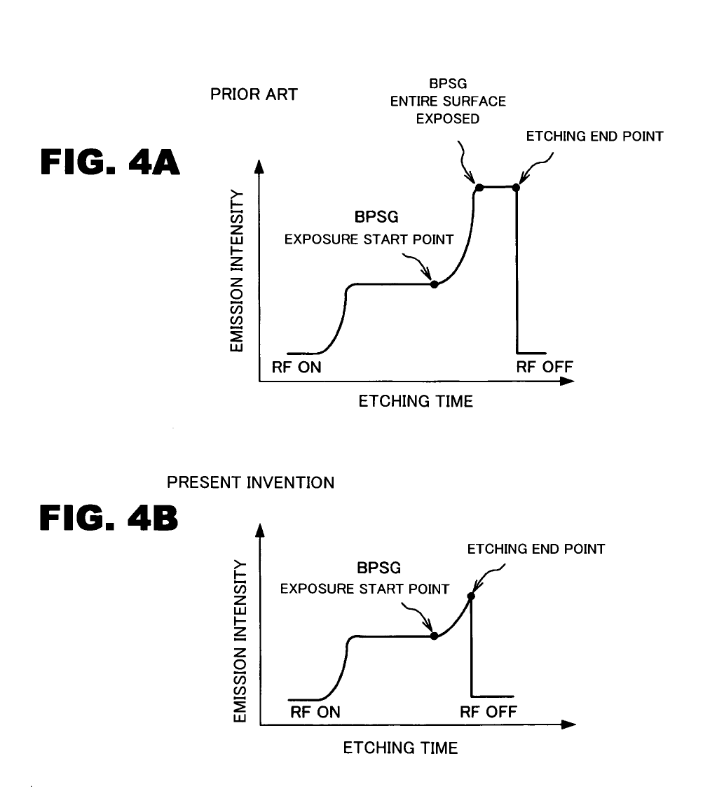

A progress status of the etching can be comprehended by observing a temporal change of the light intensity of the plasma emission of the oxygen atoms (hereinafter, referred to as an “emission intensity”) through the observation window 44, the filter 46, and the light sensor 48. FIG. 4A is a graph showing a temporal change of the emission intensity in the conventional etching-back process, and FIG. 4B is a graph showing a temporal change of the emission intensity in the etching-back process of the present invention.

In the conventional etching-back process, as shown in FIG. 4A, when the high frequency power supply 44 is turned on (RF ON) to start the etching, the emission intensity rapidly increases to reach a certain value and keeps the value. When the “exposure start point” at which a part of the BPSG film 14 is exposed is reached, the emission intensity increases resulting from the oxygen generated from the BPSG film 14. The emission intensity continues increasing to the “entire-surface exposed point” at which the entire surface of the BPSG film 14 is exposed, reaches a certain value, and keeps the value. In the conventional etching-back process, after the emission intensity becomes constant again, the high frequency power supply 44 is turned off (RF OFF) to end the etching.

In the present invention, as shown in FIG. 4B, after the “exposure start point” is passed and before the “entire-surface exposed point” is reached, the high frequency power supply 44 is turned off (RF OFF) to end the etching. Thereby, a problem in that the planarization of the insulating film is locally deteriorated resulting from the oxygen generated from the BPSG film 14 can be avoided to implement the planarization of the insulating film and to inhibit the unevenness of the film thickness of the insulating film.

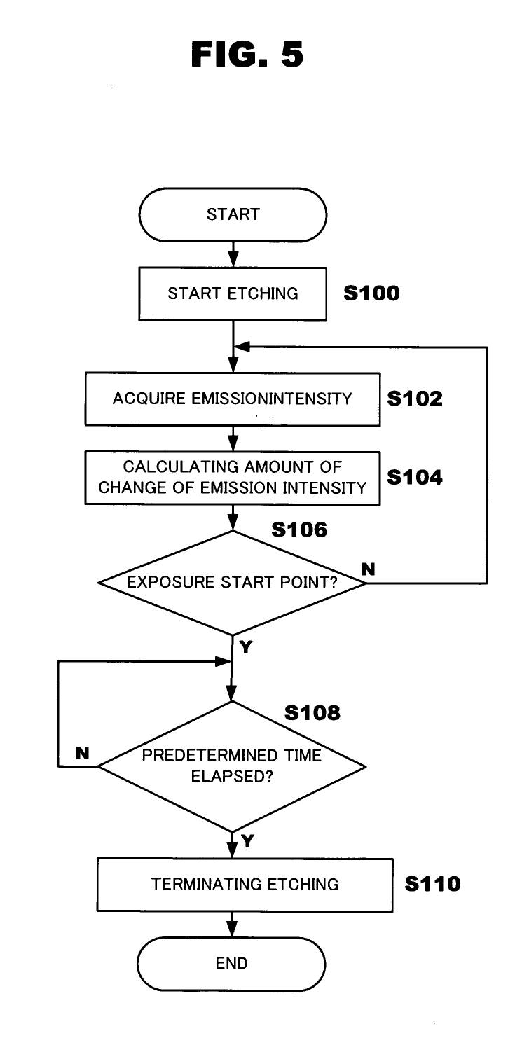

FIG. 5 is a flowchart showing a process routine of the etching control process.

When an “etching start” is instructed from an input device not shown, the computer 52 starts a routine of the etching control process. At this time, the processed object 38 is already mounted on the lower electrode 40, and through the gas inlet 34, the reactive gas is already introduced in the vacuum chamber 32.

Firstly, at step 100, the high frequency power supply 44 is turned on. Thereby, the etching is started. Subsequently, at step 102, the electrical signal indicative of the light intensity (emission intensity) of the plasma emission of the oxygen atoms is acquired from the light sensor 48, and is stored in the RAM. At subsequent step 104, the emission intensity acquired last time is read out from the RAM, and from the emission intensity acquired last time and that acquired this time, a change amount of the emission intensity is computed. As described above, once the etching is started, the emission intensity rapidly increases to reach a certain value and keeps the value. However, when the “exposure start point” is reached, the emission intensity rapidly increases again.

Subsequently, at step 106, from the change amount of the emission intensity, it is determined whether the “exposure start point” is reached. When the “exposure start point” is not reached, a negative determination is made, and the process returns to the step 102 to repeat acquiring the emission intensity and computing the change amount. When it is determined that the “exposure start point” is reached, a positive determination is made, and the process advances to subsequent step 108.

Thereafter, at step 108, it is determined whether a predetermined time is elapsed from the “exposure start point”. That is, the “etching end point” is previously set after a predetermined time from the “exposure start point” so that the etching is ended before the “entire-surface exposed point” is reached, and in this state, it is determined whether the “etching end point” is reached. Detection of the “etching end point” in this way is called an “etching end point detection (EPD)”.

The step 108 is repeated until a predetermined time is elapsed, and when it is determined that the predetermined time is elapsed (the “etching end point” is reached), a positive determination is made, and the process advances to subsequent step 110. At subsequent step 110, the high frequency power supply 44 is turned off. Thereby, the etching is stopped, and the routine is ended.

As described above, in the present embodiment, on the semiconductor substrate formed thereon with a circuit pattern, a BPSG film and an SOG film, as an insulating film, are formed in this order, and after the “exposure start point” at which a part of the BPSG film is exposed is reached, the etching of the insulating film is ended before the “entire-surface exposed point” at which the entire surface of the BPSG film is exposed is reached. Thus, a problem in that planarization of the insulating film is locally deteriorated resulting from the oxygen generated from the BPSG film can be avoided to implement the planarization of the insulating film and to inhibit unevenness of the film thickness of the insulating film.

Resulting from the above-described planarization of the insulating film, a resist mask for forming a wiring pattern on the insulating film can be accurately formed. As a result, the resist mask can be used to accurately form the wiring pattern. When the unevenness of the film thickness of the insulating film is inhibited, a difference in aspect ratio between the contact hole formed in the stepped portion and that formed in the planarized portion is lowered, and thus, it becomes easy to process the contact hole.

The temporal change of the plasma emission intensity of oxygen atoms is observed to detect the above-described “exposure start point”, and the EPD detection in which the “etching end point” is set using the “exposure start point” as a reference is performed. Thus, the etching can be ended in a timely fashion and with good reproducibility.

In the above-described embodiment, a description is give of an example where the “etching end point” is set after a predetermined time from the “exposure start point”. However, the “exposure start point” may be the “etching end point”.

Further, a description is given of an example where the BPSG film is formed as the insulating film. However, instead of the BPSG film, another CVD oxide silicon film may be used therefor.

### EXAMPLES

### Example 1

A semiconductor substrate formed thereon with a circuit pattern such as an aluminum wiring was prepared. The semiconductor substrate has a step of about 300 nm. On the semiconductor substrate, as an insulating film, a BPSG film having a film thickness of 500 nm was formed. The BPSG film is nearly constant in thickness, and on a surface of the BPSG film, a step created by the circuit pattern is reflected. Subsequently, an SOG film was formed on the BPSG film. The SOG film is formed to bury the step on the surface of the BPSG film so that the surface is nearly planarized. The SOG film has a film thickness of about 450 nm at a thickest portion and has that of about 150 nm at a thinnest portion.

An etching apparatus having the same configuration as that shown in FIG. 1 was used. The semiconductor substrate formed thereon with the BPSG film and the SOG film was mounted on a lower electrode inside a vacuum chamber. Reactive gas obtained by mixing trifluoromethane (CHF₃) and oxygen (O₂) was introduced, and a high frequency voltage was applied to generate a plasma. In this way, plasma etching was started. A temporal change of a plasma emission intensity of oxygen atoms was observed, and as a result of an EPD detection, the etching was ended after a predetermined time was elapsed from an “exposure start point” at which a part of the BPSG film was exposed.

The semiconductor substrate was extracted from the etching apparatus, and the film thickness, etc., of the insulating film were measured by an ellipsometer. It was found that in the SOG film, a depth of about 200 nm from the surface was removed by the etching. The surface exposed by the etching was planarized, and the step was reduced to about 250 nm in height. The etched insulating film has a film thickness of about 500 nm at a thickest portion and has that of about 450 nm at a thinnest portion.

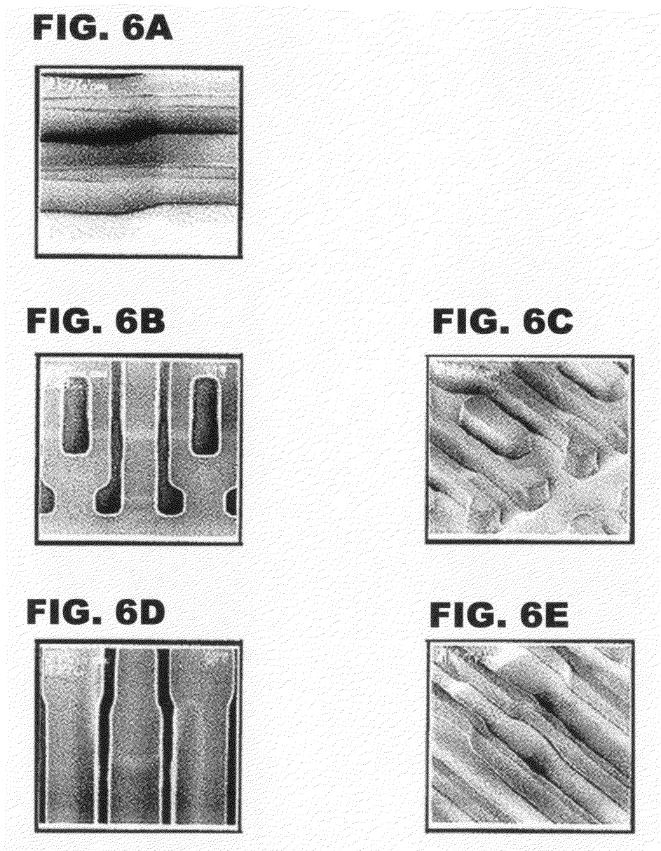

On the semiconductor substrate of which the insulating film was planarized, a resist pattern having a thickness of 960 nm was formed, and by means of a scanning electron microscope (SEM), a surface observation was performed. A picture which is viewed from obliquely above the surface of the insulating film formed thereon with the resist pattern for a step observation is a cross-sectional SEM picture shown in FIG. 6A. A light-colored portion is the surface of the insulating film. On the insulating film, two columns of linear resist patterns are formed in parallel.

A picture which is viewed from immediately above the surface for observing a notch generated location (1) is a surface SEM picture shown in FIG. 6B, and that which is viewed from obliquely thereabove is a cross-sectional SEM picture shown in FIG. 6C. Likewise, a surface SEM picture for observing a notch generated location (2) is shown in FIG. 6D, and a cross-sectional SEM picture therefor is shown in FIG. 6E. A dark portion is a convex portion, and a light-colored portion is a concave portion.

### Comparative Example 1

A semiconductor substrate formed thereon with a circuit pattern such as an aluminum wiring was prepared. For the semiconductor substrate, the same substrate as that in the example 1 was used. On the semiconductor substrate, as an insulating film, a BPSG film having a film thickness of 500 nm was formed. The BPSG film is nearly constant in thickness, and on a surface of the BPSG film, a step created by the circuit pattern is reflected.

To the semiconductor substrate formed thereon with the BPSG film, a process of planarizing the insulating film by a heat flow was applied under the condition of a temperature of 850° C. to 950° C. and a time for 15 to 30 minutes in a nitrogen atmosphere. The film thickness, etc., of the insulating film were measured by an ellipsometer. On the surface of the BPSG film, a step of about 300 nm still continued to remain.

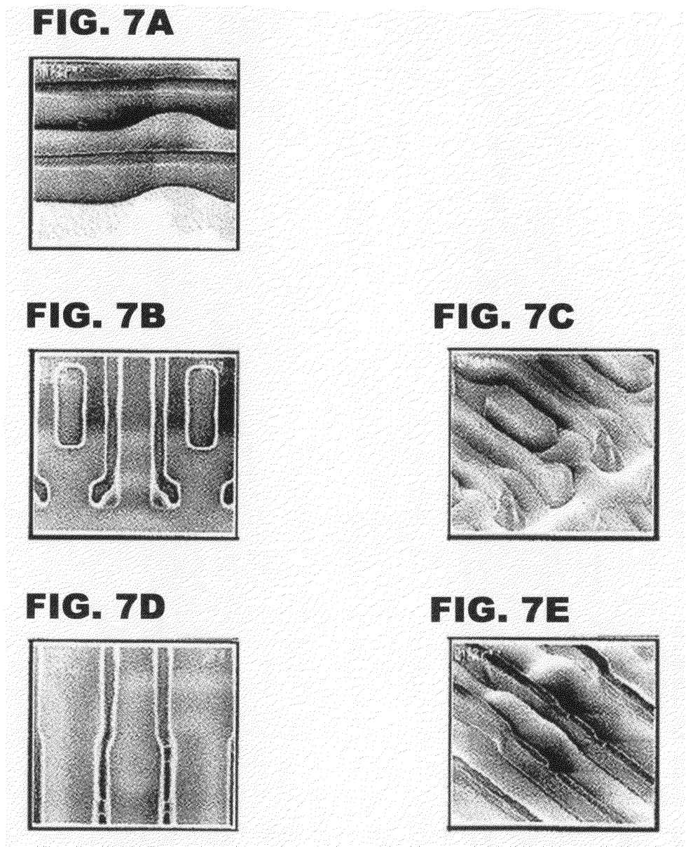

On a semiconductor substrate on which a planarization process by a heat flow was applied to an insulating film, a resist pattern having the same thickness as that in the example 1 was formed, and the surface observation was performed by means of the SEM. A picture which is viewed from obliquely above the surface of the insulating film formed thereon with the resist pattern for a step observation is a cross-sectional SEM picture shown in FIG. 7A. A picture which is viewed from immediately above the surface for observing a notch generated location (1) is a surface SEM picture shown in FIG. 7B, and that which is viewed from obliquely thereabove is a cross-sectional SEM picture shown in FIG. 7C. Likewise, a surface SEM picture for observing a notch generated location (2) is shown in FIG. 7D, and a cross-sectional SEM picture therefor is shown in FIG. 7E.

### Comparative Example 2

Similar to the example 1, on a semiconductor substrate formed thereon with a circuit pattern, a BPSG film and an SOG film were formed. An etching apparatus having the same configuration as that shown in FIG. 1 was used. The semiconductor substrate formed thereon with the BPSG film and the SOG film was mounted on a lower electrode inside a vacuum chamber. Similar to the example 1, reactive gas obtained by mixing trifluoromethane (CHF₃) and oxygen (O₂) was introduced, and a high frequency voltage was applied to generate a plasma. In this way, plasma etching was started. A temporal change of a plasma emission intensity of oxygen atoms was observed, and after the “entire-surface exposed point” at which the entire surface of the BPSG film was exposed was elapsed, the etching was ended.

The semiconductor substrate was extracted from the etching apparatus, and the film thickness, etc., of the insulating film were measured by an ellipsometer. It was found that in the SOG film, a depth of about 450 nm from the surface was removed by the etching. The surface exposed by the etching was planarized, and the step was reduced to approximately 0 nm in height. The etched insulating film has a film thickness of about 500 nm at a thickest portion and has that of about 200 nm at a thinnest portion.

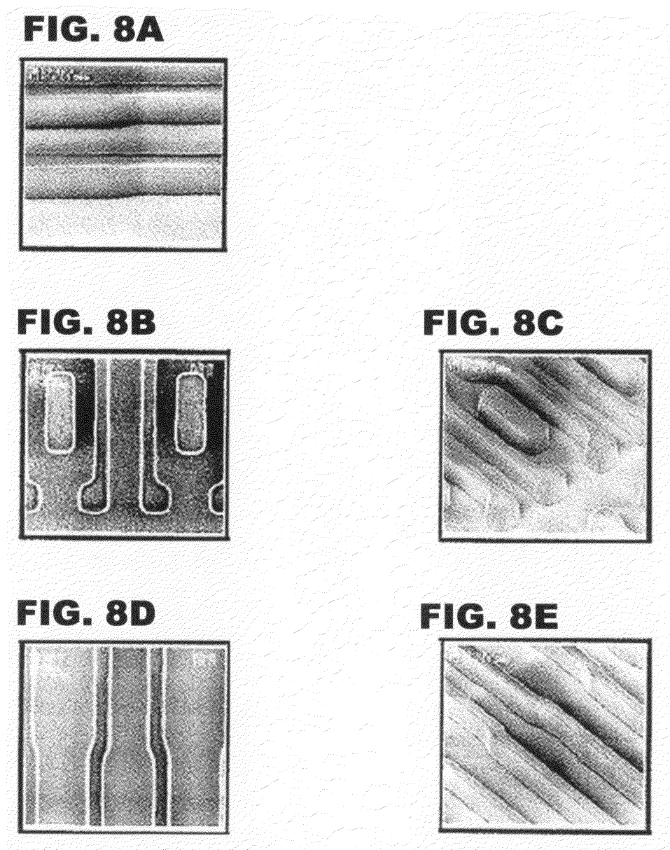

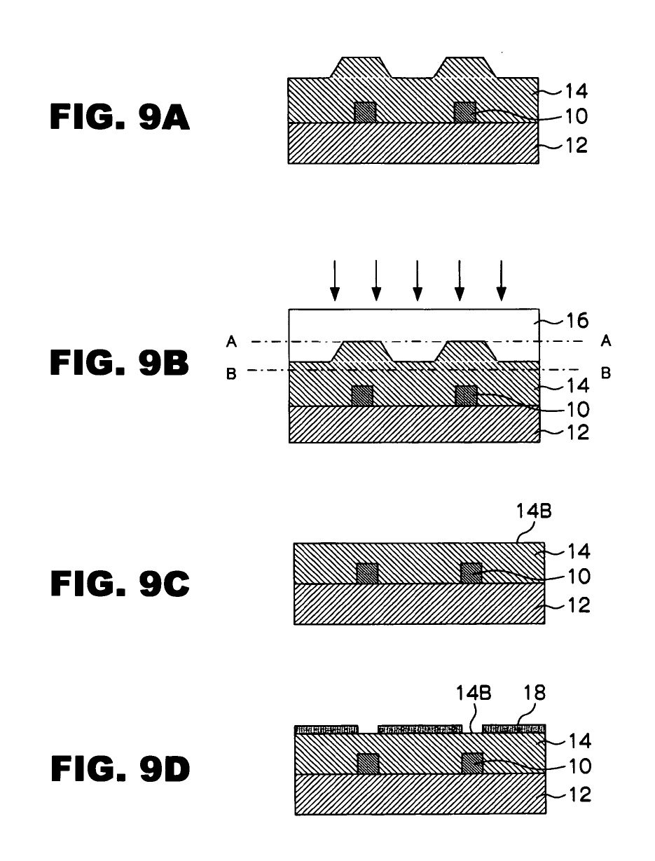

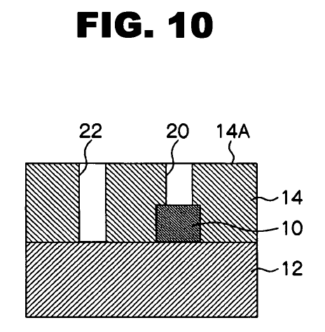

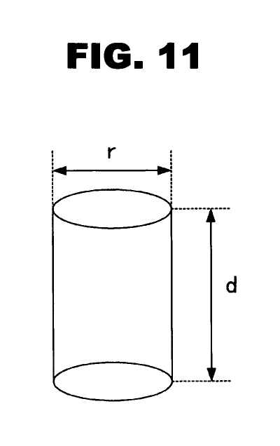

On the semiconductor substrate on which a planarization process of the insulating film was performed, a resist pattern having the same thickness as that in the example 1 was formed, and by means of the SEM, the surface observation was performed. A picture which is viewed from obliquely above the surface of the insulating film formed thereon with the resist pattern for the step observation is a cross-sectional SEM picture shown in FIG. 8A. A picture which is viewed from immediately above the surface for observing a notch generated location (1) is a surface SEM picture shown in FIG. 8B, and that which is viewed from obliquely thereabove is a cross-sectional SEM picture shown in FIG. 8C. Likewise, a surface SEM picture for observing a notch generated location (2) is shown in FIG. 8D, and a cross-sectional SEM picture therefor is shown in FIG. 8E.

With respect to the thickness of the planarization-processed insulating film, when the EPD detection was made, and then, the etching was ended after a predetermined time was elapsed from the “exposure start point” (example 1, hereinafter referred to as an “EB just process”), the film thickness is about 500 nm at a thickest portion and about 450 nm at a thinnest portion. On the other hand, when the etching is ended after the “entire-surface exposed point” is passed (example 2, hereinafter referred to as an “after-EB process”), the film thickness is about 500 nm at a thickest portion and about 200 nm at a thinnest portion.

It can be seen from this that in the example 1 in which the “EB just process” is performed, the unevenness of the film thickness of the insulating film is better inhibited as compared to the comparative example 2 in which the “after-EB process” is performed. When the unevenness of the film thickness of the insulating film is inhibited, a difference in aspect ratio between the contact hole formed in the stepped portion and that formed in the planarized portion is lowered, and thus, it becomes easy to process the contact hole.

As can be seen from the result of the SEM observation, in the example 1 (FIG. 6A) in which the “EB just process” is performed, a slightly greater influence of the step of the insulating film on the resist pattern is left than in the comparative example 2 in which the “after-EB process” is performed (FIG. 8A). However, as compared to the comparative example 1 (FIG. 7A) in which the heat flow process is performed, the influence of the step of the insulating film is reduced significantly.

Further, as can be seen from the result of the SEM observation of the notch generated location (1), in the comparative example 1 (FIG. 7B and FIG. 7C) in which the heat flow process is performed, a part of the pattern is missing, and thus, a “notch” is generated. However, in the example 1 (FIG. 6B and FIG. 6C) in which the “EB just process” is performed, the pattern is formed accurately. With respect to the pattern accuracy, the example 1 can be favorably compared even to the comparative example 2 (FIG. 8B and FIG. 8C) in which the “after-EB process” is performed.

As can be further seen from the result of the SEM observation of the notch generated location (2), in the comparative example 1 (FIG. 7D and FIG. 7E) in which the heat flow process is performed, a corner of a pattern convex portion is collapsed, and as a result, a side surface becomes irregular, resulting in the generation of the “notch”. However, in the example 1 (FIG. 6D and FIG. 6E) in which the “EB just process” is performed, the pattern is formed accurately. With respect to the pattern accuracy, the example 1 can be favorably compared to the comparative example 2 (FIG. 8D and FIG. 8E) in which the “after-EB process” is performed.

As can be seen from these results of the SEM observation, in the example 1 in which the “EB just process” is performed, the planarization of the insulating film enables the resist pattern to be formed more accurately on the insulating film as compared to the comparative example 1 in which the heat flow process is performed. With respect to a manufacturing accuracy of the resist pattern, the example 1 is equivalent to the comparative example 2 in which the “after-EB process” is performed.

As described above, it can be seen that in the example 1 in which the “EB just process” is performed, the planarization of the insulating film is implemented, and the unevenness of the film thickness of the insulating film is inhibited as well. In contrary, in the comparative example 1 in which the heat flow process is performed, the planarization of the insulating film is insufficient, and in the comparative example 2 in which the “after-EB process” is performed, the unevenness of the film thickness of the insulating film is generated.

What is claimed is:

1. A method for fabricating a semiconductor device, comprising:
forming on a semiconductor substrate having a circuit pattern thereon, a silicon oxide film and a spin on glass film (SOG film), as an insulating film, in this order;
flattening the insulating film by plasma etching;
observing a change of a plasma emission intensity of oxygen atoms during the etching to detect an exposure start point of the silicon oxide film of which the plasma emission intensity becomes constant, and then, starts increasing again; and
ending the plasma etching at the exposure start point or within a predetermined time from the exposure start point.

2. The method for fabricating a semiconductor device according to claim 1, wherein
the plasma etching is ended before an entire-surface exposed point of the silicon oxide film of which the plasma emission intensity becomes constant again.

3. The method for fabricating a semiconductor device according to claim 1, wherein
the silicon oxide film is a silicon oxide film (BPSG film) to which phosphorus and boron are added.
